(19) United States
(12) Patent Application Publication
(10) Pub. No.: US 2011/0316043 A1
(43) Pub. Date: Dec. 29, 2011

(54) Thin Group IV Semiconductor Structures

(75) Inventors: John Kouvetakis, Mesa, AZ (US); Jose Menendez, Tempa, AZ (US)

(73) Assignee: Arizona Board of Regents, Scottsdale, AZ (US)

(21) Appl. No.: 13/062,022

(22) PCT Filed: Sep. 16, 2009
(86) PCT No.: PCT/US2009/057214

§ 371 Date: Jul. 6, 2011

Related U.S. Application Data
(60) Provisional application No. 61/097,272, filed on Sep. 16, 2008.

(51) Int. Cl. H01L 29/12; H01L 21/20

(52) U.S. Cl. 257/183; 438/478; 257/E29.068; 257/E21.09

(57) ABSTRACT

Thin group IV semiconductor structures are provided comprising a thin Si substrate and a second region formed directly on the Si substrate, where the second region comprises either (i) a Ge1₋ₓSnₓ layer; or (ii) a Ge layer having a threading dislocation density of less than about 10⁵/cm², and the effective bandgap of the second region is less than the effective bandgap of the Si substrate. Further, methods for preparing the thin group IV semiconductor structures are provided. Such structures are useful, for example, as components of solar cells.

### CROSS-REFERENCE TO RELATED APPLICATIONS

This application claims the benefit of the filing date of U.S. Provisional Application Ser. No. 61/097,272, filed Sep. 16, 2008, which is hereby incorporated by reference in its entirety.

### STATEMENT OF GOVERNMENT FUNDING

The invention described herein was made in part with government support under grant number DEFG3608GO18003, awarded by the Department of Energy; and grant number FA9560-60-01-0442, awarded by the United States Air Force Multidisciplinary University Research Initiative Program. The United States Government has certain rights in the invention.

### FIELD OF THE INVENTION

The invention relates to semiconductor structures comprising Group IV semiconductor layers, and, in particular, the use of such structures as active components in solar cells.

### BACKGROUND OF THE INVENTION

Crystalline Si represented 91% of the solar cell market in 2006. This market share has expanded from 73% in 1992 to 86% in 1998 to today's value (see, Slaoui and Collins, MRS Bull. 2007, 32, 211; and Atwater et al. in Photovoltaics for the 21st Century (Electrochemical Society, 1999), Vol. 99-11, p. 206). About 42% of the crystalline Si submarket is covered by bulk single-crystal cells. (see, Slaoui, supra) There are several reasons for this spectacular success (see, Swanson, Prog. Photovoltaics: Res. Appl. 2006, 14, 443), from the ability to benefit from technological breakthroughs in the microelectronics industry to the simple fact that the band gap of Si at E_{g}=1.1 eV is very close to the optimal theoretical value of E_{g}=1.3 eV for which the thermodynamically limited single-cell efficiency reaches a maximum value of ˜35%. More realistic estimates including recombination in the intrinsic layer in pin diodes as well as dark current due to midgap defects brings the theoretical efficiency of the Si cell to about 25% (see, Meillaud et al., Solar Energy Materials and Solar Cells 2006, 90, 2952). This can be compared to the experimental demonstration of 24% efficiency (see, Green et al., Prog. Photovoltaics: Res. Appl. 2003, 11, 39), and with commercial cell efficiencies that have reached 21%. Since it is apparent that single-crystal solar cell technology is approaching the maximum expected efficiency, efforts to increase the competitiveness of these cells have focused on decreasing the cell thickness and thereby reducing silicon consumption. For example, commercial cells from SunPower Corporation are currently as thin as 190 μm. The use of even thinner cells with thickness close to 25 μm has opened up new markets for silicon photovoltaics, since these cells are flexible and can be incorporated into clothing (see, Schubert and Werner, Mater Today 2006, 9, 42). Unfortunately, ultra-thin Si cells face a fundamental limitation. The lowest energy direct optical transition in this material occurs at 3.5 eV, and therefore its absorption below this threshold is very low because only phonon-assisted transitions are possible. Therefore industry is also approaching a fundamental limit when it comes to savings by reducing the Si thickness.

Therefore, there exists a need in the art to address the apparent limitations in the design of single-crystal solar cells.

### SUMMARY OF THE INVENTION

The present invention provides improved Si technology that consists of fabricating Si/Ge₁₋ₓSnₓ and/or Si/Ge tandem cells on thin Si substrate wafers (e.g., about 1 μm to about 100 μm). The advantage of this approach is suggested by FIG. 1, which shows iso-efficiency contours for tandem solar cells (i.e., having top and bottom cells).

Consider, for example, a Si-cell with a thickness of about 100 μm, which has an “effective” band gap of about 1.4 eV (as defined below). By utilizing this material as the upper cell and combining it with a lower cell with a band gap of, for example, 0.5 eV (e.g., Ge_{0.9}Sn_{0.1}), the upper limit thermodynamic efficiency is about 40%, restoring and even surpassing the upper limit for a thick Si cell. Moreover, in another example, if one considers a 10 μm Si film with an effective band gap of about 1.8 eV, a second cell band gap of 0.8 eV (e.g., pure Ge) would also have an upper limit efficiency of about 40%. Thus tandem cells utilizing Ge₁₋ₓSnₓ or Ge layers grown on thin Si substrates, as proposed here, represent the most promising approach to advance Si-cell technology.

FIG. 2 illustrates the Si thickness required to absorb 90% of the light as a function of the photon energy. The thickness of the Ge₁₋ₓSnₓ or Ge cells can be kept below 10 μm, and in some cases a thickness below 1 μm is sufficient for 90% light absorption. It is important to point out that while the growth of a Ge₁₋ₓSnₓ/Si or Ge/Si tandem cell adds to the cost of Si technology, it eliminates the need for light trapping features such as texture or a rear surface reflector, which are already incorporated in commercial 190 μm cells.

In a first aspect, the invention provides semiconductor structures comprising (a) a Si substrate having (i) a first effective bandgap; and (ii) a first thickness between about 1 and about 100 μm; and (b) a second region having (i) a second bandgap and (ii) a second thickness, wherein the second region is formed directly on the Si substrate; and the second region comprises either (i) a Ge₁₋ₓSnₓ layer; or (ii) a Ge layer having a threading dislocation density of less than about 10⁵/cm², and wherein the second bandgap is less than the first effective bandgap.

In a second aspect, the invention provides methods for preparing a semiconductor structure comprising, contacting a Si substrate with a chemical vapor under conditions sufficient to deposit a Ge or Ge₁₋ₓSnₓ layer on the Si substrate, wherein the Si substrate has a thickness between about 1 and about 100 μm.

In a third aspect, the invention provides methods for preparing a semiconductor structure comprising, contacting a Si substrate, having a thickness greater than about 100 μm, with a chemical vapor to deposit a Ge or Ge₁₋ₓSnₓ layer on the Si substrate, and backgrinding the Si substrate to a thickness of about 1 to about 100 μm.

### BRIEF DESCRIPTION OF THE DRAWINGS

FIG. 1 is an iso-efficiency plot for the upper thermodynamic limit efficiency of 2-junction cells as calculated by Meillaud (supra); the shaded rectangle corresponds to a region of interest for thin Si/Ge₁₋ₓSnₓ solar cells.

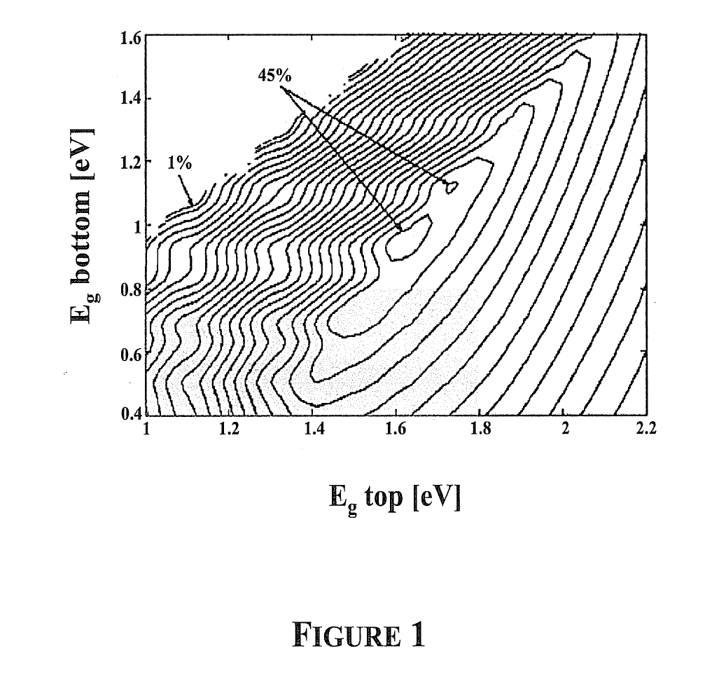

FIG. 2 is a graph illustrating the required thickness for the absorption of 90% of the light in Si and Ge_{0.86}Sn_{0.14}.

FIG. 3 is a schematic band diagram of the proposed Si/GeSn tandem solar cell; the band lineup at the Si/GeSn interface is staggered (Type II), so that no tunnel junction is required.

FIG. 4 shows an XTEM of a Ge films grown on Si(100) at 360° C.; (a) Phase contrast micrograph showing a 2.5 μm film thickness with a flat surface; (b) Diffraction contrast micrograph of a 0.8 μm film showing an atomically smooth surface and absence of penetrating defects; and (c) high-resolution image of the heteroepitaxial interface showing the location of Lomer defects providing strain relief.

FIG. 5 is a graph illustrating the absorption coefficient of Ge₁₋ₓSnₓ. Enhanced absorption above 0.4 eV suggests applications of these materials as photovoltaic components. Inset: absorption coefficients of Ge_{0.98}Sn_{0.02} and pure Ge showing a tenfold increase of absorption at 1.55 μm.

FIG. 6 shows a Ge on Si film with a thickness of 5 μm and a flat surface (top); the inset shows fraction of the solar spectrum captured by Ge (upper line) and corresponding GaAs-filtered solar spectrum captured by Ge (lower line), reflection effects are ignored; bottom left shows the (224) reciprocal space indicating a fully relaxed Ge/Si(100) heterostructure; bottom right shows an AFM image of the Ge surface showing atomic step heights.

FIG. 7 shows a SIMS profile of a p-i Ge structure showing a chemically abrupt transition between the layers; the B content is 1.5×10¹⁸ atoms per cm³.

### DETAILED DESCRIPTION OF THE INVENTION

The term “region” as used herein, means a single-layer or a multi-layer structure.

The term “lattice matched” as used herein means that the two referenced materials have the same or lattice constants differing by up to +/−0.2%. For example, GaAs and AlAs are lattice matched, having lattice constants differing by ˜0.12%.

The term “layer” as used herein, means a continuous region of a material (e.g., an alloy) that can be uniformly or non-uniformly doped and that can have a uniform or a non-uniform composition across the region.

The term “bandgap” as used herein means the energy difference between the highest occupied state of the valence band and the lowest unoccupied state of the conduction band of the material.

The term “effective bandgap” as used herein means the cutoff point at which a reference material sample can absorb greater than about 90% of incident photons having a photon energy greater than the cutoff point. For example, a sample having an effective bandgap of 1.8 eV can absorb greater than about 90% of incident photons having a photon energy greater than about 1.8 eV.

The term “thermodynamic efficiency” as used herein means the percentage of incident sunlight that the referenced structure or device can convert to electrical energy.

The term “p-doped” as used herein means atoms have been added to the material to increase the number of free positive charge carriers.

The term “n-doped” as used herein means atoms have been added to the material to increase the number of free negative charge carriers.

The term “intrinsic semiconductor” as used herein means a semiconductor material in which the concentration of charge carriers is characteristic of the material itself rather than the content of impurities (or dopants).

The term “compensated semiconductor” refers to a semiconductor material in which one type of impurity (or imperfection, for example, a donor atom) partially (or completely) cancels the electrical effects on the other type of impurity (or imperfection, for example, an acceptor atom).

It should be understood that when a layer is referred to as being “on” or “over” another layer or substrate, it can be directly on the layer or substrate, or an intervening layer may also be present. It should also be understood that when a layer is referred to as being “on” or “over” another layer or substrate, it may cover the entire layer or substrate, or a portion of the layer or substrate.

It should be further understood that when a layer is referred to as being “directly on” or “directly over” another layer or substrate, the two layers are in direct contact with one another with no intervening layer. It should also be understood that when a layer is referred to as being “directly on” or “directly over” another layer or substrate, it may cover the entire layer or substrate, or a portion of the layer or substrate.

In the first aspect, the invention provides semiconductor structures comprising (a) a Si substrate having (i) a first effective bandgap; and (ii) a first thickness between about 1 and about 100 μm; and (b) a second region having (i) a second bandgap and (ii) a second thickness, wherein the second region is formed directly on the Si substrate; and the second region comprises either (i) Ge₁₋ₓSnₓ layer; or (ii) a Ge layer having a threading dislocation density of less than about 10⁵/cm², and wherein the second bandgap is less than the first effective bandgap.

The Si substrate can comprise or consist essentially of Si, n-doped Si, p-doped Si, semi-insulating Si, intrinsic Si, or compensated Si. In certain preferred embodiments, the Si substrate comprises or consists essentially of an intrinsic Si substrate, a compensated Si substrate, a semi-insulating Si substrate, or a silicon-on-insulator (SOI) substrate (e.g., single-faced Si surface layer on SiO₂ or double-faced Si with a first and second Si surface layer each over an embedded SiO₂ layer). In another preferred embodiment, the Si substrate comprises or consists essentially of Si(100), n-doped Si(100), p-doped Si(100), semi-insulating Si(100), compensated Si(100), or intrinsic Si(100).

In certain preferred embodiments, the Si substrate is p-doped and the second region is n-doped. In certain other preferred embodiments, the Si substrate is n-doped and the second region is p-doped.

In certain preferred embodiments, the Si substrate can have a first thickness between about 8 μm and about 100 μm. In other preferred embodiments, the Si substrate can have a thickness between about 10 μm and about 100 μm, about 20 μm and about 100 μm, about 30 μm and about 100 μm, about 40 μm and about 100 μm, about 50 μm and about 100 μm, about 60 μm and about 100 μm, about 70 μm and about 100 μm, about 80 μm and about 100 μm, or about 90 μm and about 100 μm. In yet other preferred embodiments, the Si substrate can have a thickness between about 10 μm and about 75 μm, about 20 μm and about 75 μm, about 30 μm and about 75 μm, about 40 μm and about 75 μm, about 50 μm and about 75 μm, or about 60 μm and about 75 μm. In yet other preferred embodiments, the Si substrate can have a thickness between about 10 μm and about 50 μm, about 20 μm and about 50 μm, about 30 μm and about 50 μm, or about 40 μm and about 50 μm.

In other preferred embodiments, the Si substrate can have a first effective band gap between about 1.0 eV and about 1.8 eV. For example, the Si substrate can have a first effective band gap between about 1.0 eV and about 1.7 eV, or about 1.0 eV and about 1.6 eV, or about 1.0 eV and about 1.5 eV, or about 1.0 eV and about 1.4 eV, or about 1.0 eV and about 1.3 eV, or about 1.0 eV and about 1.2 eV, or about 1.0 eV and about 1.1 eV. In other preferred embodiments, the Si substrate can have a first effective band gap between about 1.1 eV and about 1.8 eV, or about 1.2 eV and about 1.8 eV, or about 1.3 eV and about 1.8 eV, or about 1.4 eV and about 1.8 eV, or about 1.5 eV and about 1.8 eV, or about 1.6 eV and about 1.8 eV, or about 1.7 eV and about 1.8 eV. In further preferred embodiments, the Si substrate can have a first effective band gap between about 1.1 eV and about 1.7 eV, or about 1.2 eV and about 1.7 eV, or about 1.3 eV and about 1.7 eV, or about 1.4 eV and about 1.7 eV, or about 1.5 eV and about 1.7 eV, or about 1.6 eV and about 1.7 eV, or about 1.2 eV and about 1.6 eV, or about 1.3 eV and about 1.6 eV, or about 1.4 eV and about 1.6 eV, or about 1.5 eV and about 1.6 eV.

Further, the Si substrate can have a diameter of at least 3 inches, at least 4 inches, or at least 6 inches. In one preferred embodiment, the Si substrate can have a diameter of about 3 inches to 6 inches; or in another example, a diameter of 6 inches to 12 inches. In other preferred embodiments, the Si substrate can have a diameter of 8 inches to 12 inches.

In a preferred embodiment of any of the preceding embodiments of the first aspect, the second region comprises a Ge₁₋ₓSnₓ layer. For example, the second region can comprise a Ge₁₋ₓSnₓ layer wherein x is about 0.01 to about 0.20. In another preferred embodiment, the second region can comprise a Ge₁₋ₓSnₓ layer wherein x is about 0.01 to about 0.19, or about 0.01 to about 0.18, or about 0.01 to about 0.17, or about 0.01 to about 0.16, or about 0.01 to about 0.15, or about 0.01 to about 0.14, or about 0.01 to about 0.13, or about 0.01 to about 0.12, or about 0.01 to about 0.11, or about 0.01 to about 0.10, or about 0.01 to about 0.09, or about 0.01 to about 0.08, or about 0.01 to about 0.07, or about 0.01 to about 0.06, or about 0.01 to about 0.05. In yet another preferred embodiment, the second region can comprise a Ge₁₋ₓSnₓ layer wherein x is about 0.02 to about 0.20, or about 0.03 to about 0.20, or about 0.04 to about 0.20, or about 0.05 to about 0.20, or about 0.06 to about 0.20, or about 0.07 to about 0.20, or about 0.08 to about 0.20, or about 0.09 to about 0.20, or about 0.10 to about 0.20, or about 0.11 to about 0.20, or about 0.12 to about 0.20, or about 0.13 to about 0.20, or about 0.14 to about 0.20, or about 0.15 to about 0.20. In yet another preferred embodiment, the second region can comprise a Ge₁₋ₓSnₓ layer wherein x is about 0.01 to about 0.05, or about 0.05 to about 0.10, or about 0.05 to about 0.15, or about 0.05 to about 0.20.

In another preferred embodiment of any of the preceding embodiments of the first aspect, the second region comprises a Ge layer having a threading dislocation density of less than about 10⁵/cm², for example, a relaxed Ge layer having a threading dislocation density of less than about 10⁵/cm².

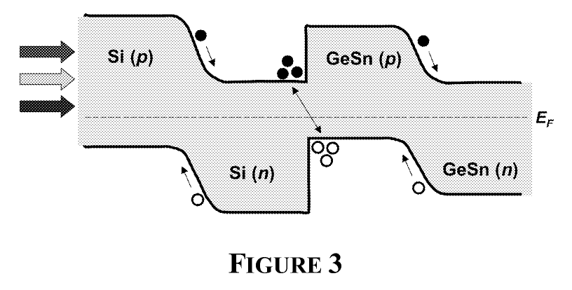

In any of the preceding embodiments of the first aspect, a tunnel junction may be formed between the first and second regions. However, generally, the band alignment between the first region, comprising the Si substrate, and the second region, comprising Ge or GeSn layer as described above, is a Type II band alignment facilitating the design of a tandem cell. Such Type II alignments do not require a tunnel junction between the two adjoining regions. For example, the valence band offset between relaxed Ge and Si is about 0.8 eV, higher on the Ge side (see, Van de Walle, Phys. Rev. B 1989, 39, 1871). Since the band gap is 0.7 eV in Ge and 1.1 eV in Si, the conduction band is also higher on the Ge-side of the heterojunction, i.e., the band alignment is of Type II (see, FIG. 3). GeSn alloys have smaller band gaps than Ge, but for all practical Sn concentrations the alignment will remain Type II.

The second region can have a second thickness between about 0.1 μm and about 10 μm. In one preferred embodiment, the second region can have a thickness between about 0.2 μm and about 10 μm, or about 0.5 μm and about 10 μm, or about 1.0 μm and about 10 μm, or about 2 μm and about 10 μm, or about 3 μm and about 10 μm, or about 4 μm and about 10 μm, or about 5 μm and about 10 μm. In other preferred embodiments, the thickness can be between about 0.1 μm and about 5 μm, or about 0.2 μm and about 5 μm, or about 0.5 μm and about 5 μm, or about 1.0 μm and about 5 μm, or about 2 μm and about 5 μm. In yet other preferred embodiment, the second region can have a thickness between about 0.1 μm and about 1 μm, or about 0.2 μm and about 1 μm, or about 0.3 μm and about 1 μm, or about 0.4 μm and about 1 μm, or about 0.5 μm and about 1 μm, or about 0.6 μm and about 1 μm, or about 0.7 μm and about 1 μm, or about 0.8 μm and about 1 μm, or about 0.9 μm and about 1 μm, or about 0.1 μm and about 0.5 μm, or about 0.1 μm and about 0.4 μm, or about 0.1 μm and about 0.3 μm, or about 0.1 μm and about 0.2 μm.

In a preferred embodiment, the second region can have a second bandgap between about 0.4 eV and about 1.0 eV. In one preferred embodiment, the second region can have a second bandgap between about 0.4 eV and about 0.8 eV; for example, the second bandgap is between about 0.4 eV and about 0.9 eV, or about 0.4 eV and about 0.8 eV, or about 0.4 eV and about 0.7 eV, or about 0.4 eV and about 0.6 eV, or about 0.4 eV and about 0.5 eV, or about 0.5 eV and about 1.0 eV, or about 0.6 eV and about 1.0 eV, or about 0.7 eV and about 1.0 eV, or about 0.8 eV and about 1.0 eV, or about 0.9 eV and about 1.0 eV. In other preferred embodiments, the second bandgap is between about 0.5 eV and about 0.9 eV, or about 0.5 eV and about 0.8 eV, or about 0.5 eV and about 0.7 eV, or about 0.5 eV and about 0.6 eV. In yet other preferred embodiments, the second bandgap is between about 0.6 eV and about 0.9 eV, or about 0.6 eV and about 0.8 eV, or about 0.6 eV and about 0.7 eV, or about 0.7 eV and about 0.9 eV, or about 0.8 eV and about 0.9 eV, or about 0.7 eV and about 0.8 eV.

In a particular preferred embodiment, the second region can have a second thickness between about 1 μm and about 5 μm and the Si substrate can have a first thickness of about 8 μm and about 100 μm. In another preferred embodiment, the second region can have a second thickness between about 1 μm and about 5 μm and the Si substrate can have a first thickness between about 15 μm and about 50 μm.

In a further preferred embodiment, the preceding semiconductor structures may further comprise varying quantities of carbon or tin, as desired for a given application. Inclusion of carbon or tin into the semiconductor substrates can be carried out by standard methods in the art. For example, carbon can reduce the mobility of the dopants in the structure and more specifically boron. Incorporation of Sn can yield materials with novel optical properties such as direct emission and absorption.

In certain preferred embodiments, the semiconductor structures have a thermodynamic efficiency of about 10% to about 50%; for example, the semiconductor structures can have a thermodynamic efficiency of about 15% to about 50%; or about 20% to about 50%; or about 25% to about 50%; or about 30% to about 50% or about 35% to about 50%; or about 40% to about 50%; or about 45% to about 50%. In other preferred embodiments, the semiconductor structures can have a thermodynamic efficiency of about 15% to about 45%; or about 20% to about 45%; or about 25% to about 45%; or about 30% to about 45% or about 35% to about 45%; or about 40% to 45%. In yet other preferred embodiment, the semiconductor structures can have a thermodynamic efficiency of about 15% to about 40%; or about 20% to about 40%; or about 25% to about 40%; or about 30% to about 40% or about 35% to about 40%. Further, in certain preferred embodiments, the semiconductor structures can absorb light over the entire range of relevant AM 1.5 solar wavelengths, from about 250 nm to about 2500 nm.

The semiconductor structures of any of the preceding embodiments may further comprise one or more light trapping features such as, but not limited to, texture and/or a surface reflector.

In the second aspect, the invention provides methods for preparing a semiconductor structure comprising, contacting a Si substrate with a chemical vapor under conditions suitable to deposit a Ge or Ge₁₋ₓSnₓ layer on the Si substrate, wherein the Si substrate has a thickness between about 1 μm and about 100 μm.

In the third aspect, the invention provides methods for preparing a semiconductor structure comprising, contacting a Si substrate, having a thickness greater than about 100 μm, with a chemical vapor under conditions suitable to deposit a Ge or Ge₁₋ₓSnₓ layer on the Si substrate, and backgrinding the Si substrate to a thickness of about 1 μm to about 100 μm.

In a preferred embodiment of the second and third aspects, a Ge layer having a threading dislocation density below 10⁵/cm² or below 10⁴/cm² is formed directly on the Si substrate. Pure Ge films directly on Si substrates can be grown, for example, via chemical vapor deposition (CVD; see, Wistey et al., Appl. Phys. Lett. 2007, 90, 082108; Fang et al., Chem. Mater. 2007, 19, 5910-25; and U.S. patent application Ser. No. 12/133,225, entitled, “Methods and Compositions for Preparing Ge/Si Semiconductor Substrates,” filed 4 Jun. 2008, each of which are hereby incorporated by reference in their entirety). In one preferred embodiment, the Ge layer can be formed by contacting the Si substrate with a chemical vapor comprising an admixture of (a) (H₃Ge)₂CH₂, H₃GeCH₃, or a mixture thereof; and (b) Ge₂H₆, wherein Ge₂H₆ is in excess.

In one preferred embodiment, the admixture can be an admixture of (GeH₃)₂CH₂ and Ge₂H₆ in a ratio of between 1:10 and 1:20. In another preferred embodiment, the admixture can be an admixture of GeH₃CH₃ and Ge₂H₆ in a ratio of between 1:5 and 1:30. In another preferred embodiment, the admixture can be an admixture of GeH₃CH₃ and Ge₂H₆ in a ratio of between 1:5 and 1:20. In yet another preferred embodiment, the admixture can be an admixture of GeH₃CH₃ and Ge₂H₆ in a ratio of between 1:21 and 1:30. In yet another preferred embodiment, the admixture can be an admixture of GeH₃CH₃ and Ge₂H₆ in a ratio of between 1:15 and 1:25.

In a further preferred embodiment, the admixture can be an admixture of a combination of (GeH₃)₂CH₂ and GeH₃CH₃ at a 1:5 to 1:30 ratio with Ge₂H₆. In another preferred embodiment, the admixture can be an admixture of a combination of (GeH₃)₂CH₂ and GeH₃CH₃ at a 1:5 to 1:20 ratio with Ge₂H₆. In another preferred embodiment, the admixture can be an admixture of a combination of (GeH₃)₂CH₂ and GeH₃CH₃ at a 1:21 to 1:30 ratio with Ge₂H₆. In another preferred embodiment, the admixture can be an admixture of a combination of (GeH₃)₂CH₂ and GeH₃CH₃ at a 1:15 to 1:25 ratio with Ge₂H₆. In various non-limiting preferred embodiments, the admixtures can be in ratios between 1:5 and 1:15, between 1:5 and 1:10, between 1:10 and 1:20, between 1:0 and 1:15, between 1:21 and 1:30, between 1:22 and 1:30, between 1:23 and 1:30, between 1:24 and 1:30, between 1:25 and 1:30, between 1:26 and 1:30, between 1:27 and 1:30, between 1:28 and 1:30, or between 1:29 and 1:30; or admixtures in ratios of 1:5, 1:6, 1:7, 1:8, 1:9; 1:10; 1:11; 1:12; 1:13; 1:14; 1:15.1:16, 1:17, 1:18, 1:19, 1:20, 1:21, 1:22, 1:23, 1:24, 1:25, 1:26, 1:27, 1:28, 1:29, or 1:30.

In various preferred embodiments, the gaseous precursors are provided in substantially pure form in the absence of diluants. In a preferred embodiment, the gaseous precursors are provided as a single gas mixture. In preferred embodiment, the gaseous precursors are provided intermixed with an inert carrier gas. In this embodiment, the inert gas can be, for example, H₂ or N₂ or other carrier gases that are sufficiently inert under the deposition conditions and process application.

In a further preferred embodiment, the gaseous precursor is introduced by gas source molecular beam epitaxy at between at a temperature of between about 350° C. and about 450° C., more preferably between about 350° C. and about 430° C., and even more preferably between about 350° C. and about 420° C., about 360° C. and about 430° C., about 360° C. and about 420° C., about 360° C. and about 400° C., or about 370° C. and about 380° C. Practical advantages associated with this low temperature/rapid growth process include (i) short deposition times compatible with preprocessed Si wafers, (ii) selective growth for application in high frequency devices, and (iii) negligible mass segregation of dopants, which is particularly critical for thin layers.

In various preferred embodiments, the gaseous precursor is introduced at a partial pressure between about 10⁻⁸ Torr and about 1000 Torr. In one preferred embodiment, the gaseous precursor is introduced at between about 10⁻⁷ Torr and about 10⁻⁴ Torr gas source molecular beam epitaxy or low pressure CVD. In another preferred embodiment, the gaseous precursor is introduced at between about 10⁻⁷ Torr and about 10⁻⁴ Torr for gas source molecular beam epitaxy. In yet another preferred embodiment, the gaseous precursor is introduced at between about 10⁻⁶ Torr and about 10⁻⁵ Torr for gas source molecular beam epitaxy.

n-type Ge layers can be prepared by the controlled substitution of, for example, P, As, or Sb atoms in the Ge lattice according to methods familiar to those skilled in the art. One example includes, but is not limited to, using P(SiH₃)₃ to provide n-doping through controlled substitution of P atoms.

p-Type Ge layers can be prepared by the controlled substitution of B, Al, Ga, or In atoms in the Ge lattice according to methods familiar to those skilled in the art. One example includes, but is not limited to, B substitution by use of B₂H₆.

Such p- and n-doping methods can provide Ge layers having carrier concentrations in the range of about 10¹⁷ cm⁻³ to about 10²¹ cm⁻³; or about 10¹⁷ cm⁻³ to about 10¹⁹ cm⁻³.

In another preferred embodiment of the second and third aspects, a Ge₁₋ₓSnₓ layer is formed directly on the Si substrate. Methods for preparing the Ge₁₋ₓSnₓ layers can be found, for example, in U.S. Patent Application Publication No. US2007-0020891-A1, which is hereby incorporated by reference in its entirety. For example, the Ge₁₋ₓSnₓ layer can be formed by contacting the Si substrate with a chemical vapor comprising Ge₂H₆ and SnD₄. In such embodiments, the chemical vapor can further comprise H₂.

After growth of each desired Ge₁₋ₓSnₓ layer, the semiconductor structure can be subject to a post-growth Rapid Thermal Annealing treatment. For example, the structure can be heated to a temperature of about 750° C. and held at such temperature for about 1 to about 10 seconds. The structure can be cycled multiple times between the temperature utilized for GeSn deposition (about 300° C. to about 350° C.) to about 750° C. For example, the structure can be cycled from 1 to 10, or 1 to 5, or 1 to 3 times.

n-Type Ge₁₋ₓSnₓ layers can be prepared by the controlled substitution of P, As, or Sb atoms in the Ge₁₋ₓSnₓ lattice according to methods known to those skilled in the art. One example includes, but is not limited to, the use of P(GeH₃)₃ or As(GeH₃)₃, which can furnish structurally and chemically compatible PGe₃ and AsGe₃ molecular cores, respectively (see, Chizmeshya et al., Chem. Mater. 2006, 18, 6266; and US Patent Application Publication No. 2006-0134895-A1, each of which are hereby incorporated by reference in their entirety) can give n-type Ge₁₋ₓSnₓ layers.

p-Type Ge₁₋ₓSnₓ layers can be prepared by the controlled substitution of B, Al, Ga, or In atoms in the Ge₁₋ₓSnₓ lattice according to methods known to those skilled in the art. One example includes, but is not limited to, conventional CVD reactions of SnD₄, Ge₂H₆ and B₂H₆ at low temperatures.

Such p- and n-doping methods can provide GeSn layers having carrier concentrations in the range of about 10¹⁷ cm⁻³ to about 10²¹ cm⁻³; or about 10¹⁷ cm⁻³ to about 10¹⁹ cm⁻³.

In the preceding methods, the Ge and Ge₁₋ₓSnₓ layers can have thicknesses between about 0.1 μm and about 10 μm. For example, the thickness can be between about 0.2 μm and about 10 μm, or about 0.5 μm and about 10 μm, or about 1.0 μm and about 10 μm, or about 2 μm and about 10 μm, or about 3 μm and about 10 μm, or about 4 μm and about 10 μm, or about 5 μm and about 10 μm. In other examples, the thickness can be between about 0.1 μm and about 5 μm, or about 0.2 μm and about 5 μm, or about 0.5 μm and about 5 μm, or about 1.0 μm and about 5 μm, or about 2 μm and about 5 μm. In yet other examples, the thickness can be between about 0.1 μm and about 1 μm, or about 0.2 μm and about 1 μm, or about 0.3 μm and about 1 μm, or about 0.4 μm and about 1 μm, or about 0.5 μm and about 1 μm, or about 0.6 μm and about 1 μm, or about 0.7 μm and about 1 μm, or about 0.8 μm and about 1 μm, or about 0.9 μm and about 1 μm, or about 0.1 μm and about 0.5 μm, or about 0.1 μm and about 0.4 μm, or about 0.1 μm and about 0.3 μm, or about 0.1 μm and about 0.2 μm.

In the second and third aspects, the gaseous precursors for deposition of the Ge or Ge₁₋ₓSnₓ layers can be deposited by any suitable technique, including but not limited to gas source molecular beam epitaxy, chemical vapor deposition, plasma enhanced chemical vapor deposition, laser assisted chemical vapor deposition, and atomic layer deposition. In one embodiment, the Ge or Ge₁₋ₓSnₓ layers can be formed by chemical vapor deposition or molecular beam epitaxy.

The methods of the second and third aspects can be used for preparing the semiconductor structures according to the first aspect of the invention and any embodiments thereof.

### EXAMPLES

### Example 1

### Ge/Si(100) Structures and Templates

Pure Ge films directly on Si substrates with unprecedented control of film microstructure, morphology, purity and optical properties can be grown via CVD (see, Wistey, supra; and Fang supra). Ge growth is conducted at low temperatures (about 350° C. to about 420° C.) on a single wafer reactor configuration at about 10⁻⁵ to about 10⁻⁴ Torr, in the absence of gas phase reactions using molecular mixtures of Ge₂H₆ and small amounts of highly reactive (GeH₃)₂CH₂ or GeH₃CH₃ organometallic additives.

The optimized molar ratios of these compounds have enabled layer-by-layer growth at conditions compatible with selective growth, which has recently been demonstrated by depositing patterned Ge “source/drain” structures in prototype devices. The driving force for this reaction mechanism is the facile elimination of extremely stable CH₄ and H₂ byproducts, consistent with calculated chemisorption energies and surface reactivities.

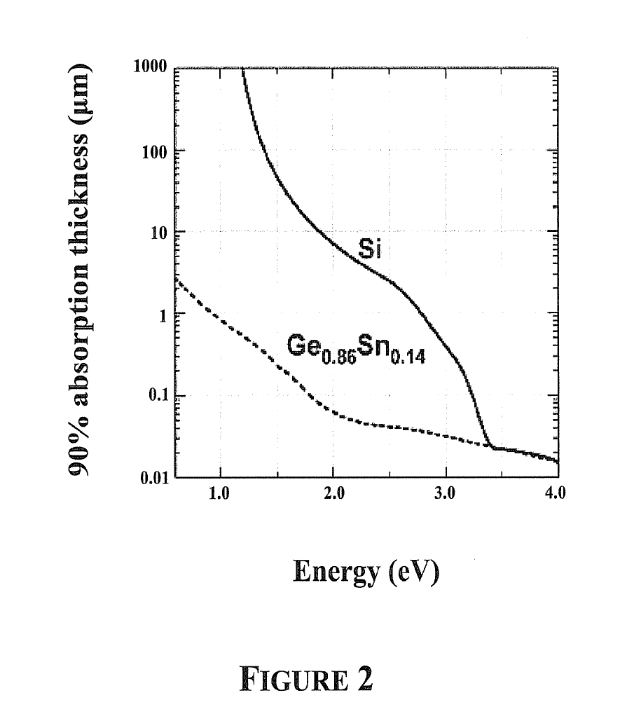

Using this approach atomically smooth (AFM RMS ˜0.2 nm) and stress-free Ge films have been produced with dislocation densities less than 10⁵ cm⁻², two orders of magnitude lower than those attainable from the best competing processes. The full relaxation in the films is readily achieved via formation of Lomer dislocations confined to the Ge/Si interface (FIG. 2) and this allows film dimensions approaching bulk values to be achieved on a Si substrate, for the first time. These defects are found to alleviate the interface strain associated with the pseudomorphic growth and suppress the propagation of dislocation cores throughout the layer as shown in etch-pit density characterizations.

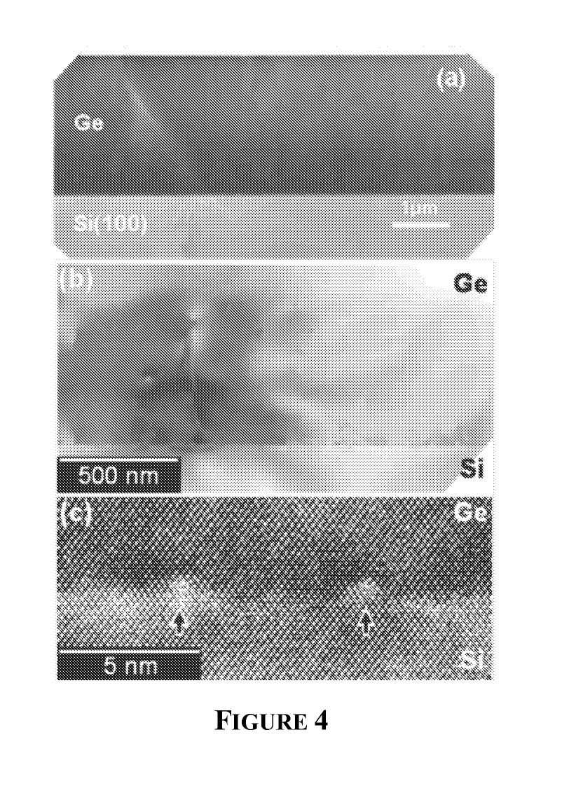

The XTEM micrographs of FIG. 4 show two representative layers with thickness up to several microns, which have been grown at extremely high growth rates up to 10 nm/min using a 15:1 molar ratio of Ge₂H₆:(GeH₃)₂CH₂, indicating that the approach is viable from a large scale commercial perspective. Raman studies of these samples confirm that the materials are virtually stress- and defect-free. Their photoreflectance signal is comparable to that of bulk Ge, and in the most perfectly relaxed films we have also observed photoluminescence, a testament to their high crystal quality, indicating their tremendous potential as new active layers material. The desirable growth conditions, low dislocations densities and superior film morphology make Ge films grown by this method an ideal platform for producing perfectly crystalline and fully epitaxial III-V epilayers suitable for photovoltaic applications.

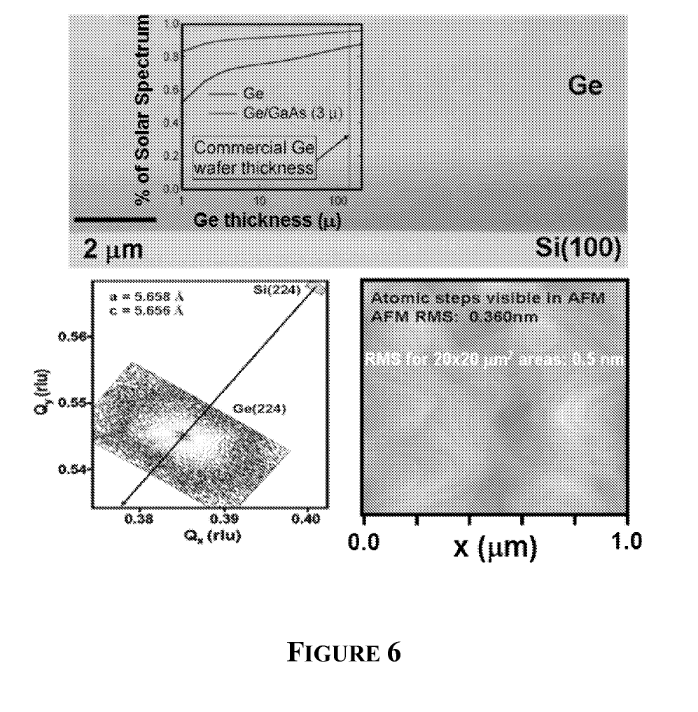

In particular, we have demonstrated growth of thick Ge films with atomically flat surfaces, strain free states and record low dislocation densities (less than 10⁵/cm²) for applications as photovoltaic junctions integrated with large area Si substrates. The results indicated that these materials can be grown with thicknesses of about 5 μm (FIG. 6) and there appears to be no upper limit to the thickness that can be achieved using our method. This achievement has immediate implications for photovoltaics due to the potential for replacing the costly and heavy Ge substrates. In this regard FIG. 6 (inset) shows that a 5 μm Ge film absorbs 85% of the GaAs-filtered light relative to the absorption by a commercial Ge substrate.

We have demonstrated the fabrication of Ge layers on large scale Si platforms with 3″-4″ diameters with superior morphology and microstructure. Here the Ge buffer layers were first grown directly on Si at 350° C. with nominal thickness of about 500 nm to about 700 nm using deposition molecular mixtures of Ge₂H₆ and small amounts of (GeH₃)₂CH₂. The layers subsequently produced were found to exhibit strain relaxed microstructures, extremely low defect densities of about 10⁴/cm², atomically flat surfaces, and Ge layers approaching 5 microns in thickness were manufactured for the first time.

### Example 2

### Doped Ge/Si(100)

The n-type doping of the Ge layers grown directly on Si can be conducted using proven protocols that have already led to the successful doping of the Ge₁₋ₓSnₓ alloys. These utilize As, Sb, P custom prepared hydride compounds such as As(GeH₃)₃, P(GeH₃)₃ and Sb(GeH₃)₃ molecules. These are co-deposited with mixtures of digermane to form Ge films incorporating the appropriate carrier type and level. In the case of As, we have been able to introduce free carrier concentrations as high as 10²⁰/cm³ in Ge₁₋ₓSnₓ via deposition of As(GeH₃)₃. These carbon-free hydrides are ideal for low temperature, high efficiency doping applications. They are designed to furnish a structural Ge₃As unit resulting inhomogeneous substitution at high concentrations without clustering or segregation. For p-type doping suitable concentrations of gaseous B₂H₆ can be mixed with the Ge precursors and reacted to obtain the desired doping level.

In one example, p-type Ge layers with thickness of about 0.7 μm to about 1.5 μm were grown using a virtually identical approach as described in Example 1, utilizing reactions of Ge₂H₆, (GeH₃)₂CH₂ and B₂H₆ to obtain carrier concentrations in the range of about 10¹⁷ cm⁻³ to about 10¹⁹ cm⁻³. The n-type counterparts were deposited on undoped Ge buffers using the (SiH₃)₃P compound as the source of P atoms yielding active carrier concentrations up to 3×10¹⁹/cm³. The secondary ion spectrometry (SIMS) profiles of the latter films showed a sharp transition at the i-Ge/n-Ge interface suggesting that the formation of a full p-i-n device structure is within reach.

The B and P concentration and corresponding transport properties in the doped samples was independently determined by SIMS and ellipsometry and the results indicated a close agreement between the two methods. The films exhibited atomically flat surfaces (RMS of about 2 Å) and fully relaxed, highly aligned structures as shown by XRD and XTEM measurements.

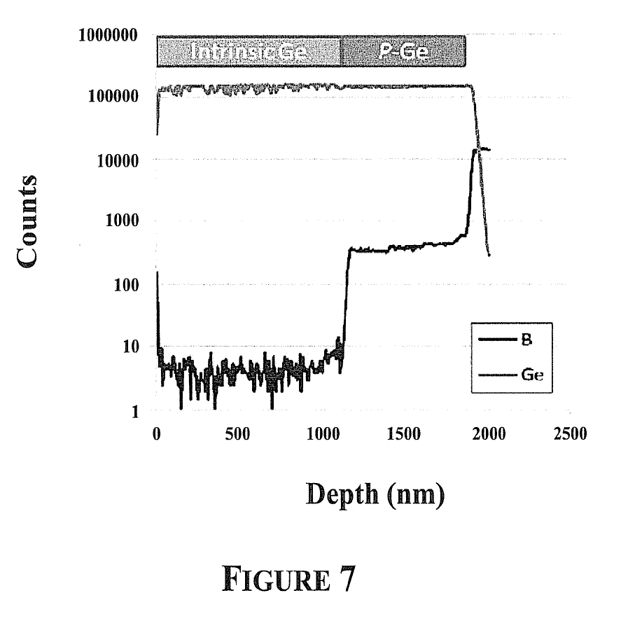

This successful demonstration of p- and n-doping was followed by attempts to assemble multilayer structures in p-i-n geometry. A typical sample consisted of about 500 nm p-type initial layer and an about 1600 nm intrinsic epilayer and exhibited superior structural and morphological properties. For example, the FWHM of the (004) reflection was about 0.05° (180 arcsecs), unprecedented for Ge film growth on mismatched Si substrates. SIMS profiles showed an abrupt transition between p-type and intrinsic Ge layer regions as shown in FIG. 7 indicating no interdiffusion of B atoms across the common heterojunction.

### Example 3

### Optoelectronic Ge_{1-y}Sn_{y} Alloys

From a fundamental view point Ge_{1-y}Sn_{y} alloys on their own right are intriguing IR materials that undergo an indirect-to-direct band gap transition with variation of their strain state and/or compositions. They also serve as versatile, compliant buffers for the growth of II-VI and III-V compounds on Si substrates.

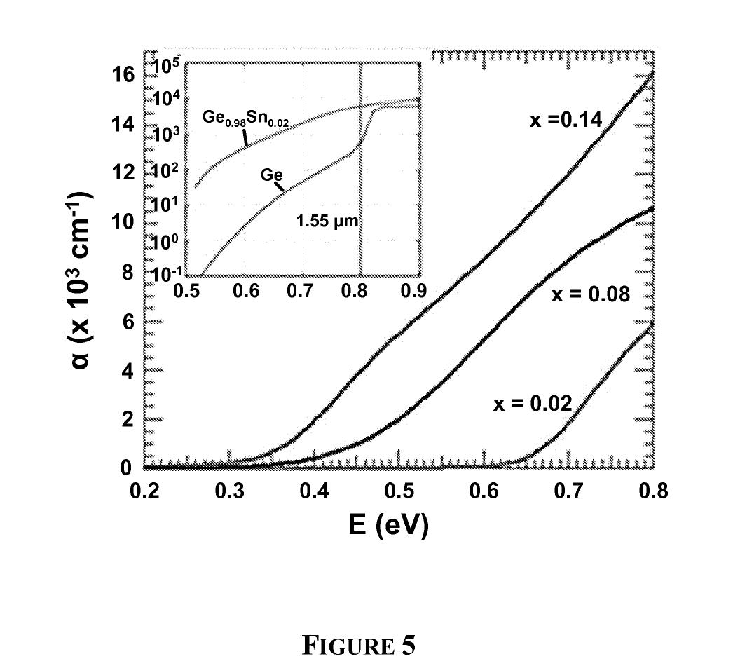

The fabrication of the Ge_{1-y}Sn_{y} materials directly on Si wafers has recently been reported using a specially developed CVD method involving reactions of Ge₂H₆ with SnD₄ in high purity H₂ (10%). Thick and atomically flat films are grown at about 250° C. to about 350° C. and possess low densities of threading dislocations (about 10⁵ cm⁻²) and high concentrations of Sn atoms up to about 20%. Since the incorporation of Sn lowers the absorption edges of Ge, the Ge_{1-y}Sn_{y} alloys are attractive for photovoltaic applications that require band gaps lower than that of Ge (0.80 eV). The absorption coefficient of selected Ge₁₋ₓSnₓ samples, showing high absorption well below the Ge band gap, is show in FIG. 5 (see, D'Costa et al., Phys. Rev. B 2006, 73, 125207).

The compositional dependence of the Ge_{1-y}Sn_{y} band structure shows a dramatic reduction of the Ge-like optical transitions (the direct gap E₀, the split-off E₀+Δ₀ gap, and the higher-energy E₁, E₁+Δ₁, E_{0′} and E₂ critical points) as a function of Sn concentration (see, D'Costa, supra). With only 15 at. % Sn, the E₀ gap is reduced by half relative to that of pure Ge (0.80 eV). The concomitant lowering of the absorption edge implies that the relevant photovoltaic wavelengths can be covered with modest amounts of Sn in the alloys. Recent electrical measurements on prototype devices based on these materials are encouraging. Hall and IR ellipsometry indicate that the as-grown material is p-type, with hole concentrations in the 10¹⁶ cm⁻³ range. This background doping is found to be due to defects in the material and can be reduced using rapid thermal annealing. This occurs with a simultaneous increase in mobility to values above 600 cm²/V-sec, suggesting that the thermal treatment is truly removing the acceptor defects rather than creating compensating donor defects.

n-type Ge₁₋ₓSnₓ layers can be prepared by the controlled substitution of active As atoms in the lattice is made possible by the use of As(GeH₃)₃, which furnishes structurally and chemically compatible AsGe₃ molecular cores (as described above). p-Type Ge₁₋ₓSnₓ layers can be prepared via conventional CVD reactions of SnD₄, Ge₂H₆ and B₂H₆ at low temperatures. Electrical measurements indicate that high carrier concentrations (about 3×10¹⁹ atoms/cm³) can be routinely achieved via these methods.

The above-described invention possesses numerous advantages as described herein and in the referenced appendices. The invention in its broader aspects is not limited to the specific details, representative devices, and illustrative examples shown and described. Accordingly, departures may be made from such details without departing from the spirit or scope of the general inventive concept.

We claim:

1. A semiconductor structure comprising
(a) a Si substrate having (i) a first effective bandgap; and (ii) a first thickness between about 1 to about 100 μm; and
(b) a second region having (i) a second bandgap and (ii) a second thickness, wherein
the second region is formed directly on the Si substrate; and
the second region comprises either
(i) a Ge₁₋ₓSnₓ layer; or
(ii) a Ge layer having a threading dislocation density of less than about 10⁵/cm²;
and
the second bandgap is less than the first effective bandgap.

2. The semiconductor structure of claim 1, wherein the structure has a thermodynamic efficiency of about 10% to about 50%.

3. The semiconductor structure of claim 1, wherein the structure has a thermodynamic efficiency of about 20% to about 50%.

4. The semiconductor structure of claim 1, wherein the structure has a thermodynamic efficiency of about 30% to about 45%.

5. The semiconductor structure of claim 1, wherein the second bandgap is between about 0.4 eV and about 1.0 eV.

6. The semiconductor structure of claim 1, wherein the first thickness is between about 8 μm and about 100 μm.

7. The semiconductor structure of claim 1, wherein the second thickness is between about 0.1 μm and about 10 μm.

8. The semiconductor structure of claim 1, wherein the second thickness is between about 1 μm and about 5 μm and the first thickness is between about 8 μm and about 100 μm.

9. The semiconductor structure of claim 1, wherein the second thickness is between about 1 μm and about 5 μm and the first thickness ranges is between about 15 μm and about 50 μm.

10. The semiconductor structure of claim 1, wherein the second region comprises Ge₁₋ₓSnₓ.

11. The semiconductor structure of claim 1, wherein the Si substrate has a diameter of at least 3 inches.

12. The semiconductor structure of claim 1, wherein the Si substrate has a diameter of at least 6 inches.

13. The semiconductor structure of claim 1 having no tunnel junction formed between the first region and the second region.

14. A method for preparing a semiconductor structure comprising, contacting a Si substrate with a chemical vapor under conditions suitable to deposit a Ge or Ge₁₋ₓSnₓ layer on the Si substrate, wherein the Si substrate has a thickness between about 1 μm and about 100 μm.

15. A method for preparing a semiconductor structure comprising,
contacting a Si substrate, having a thickness greater than about 100 μm, with a chemical vapor under conditions suitable to deposit a Ge or Ge₁₋ₓSnₓ layer on the Si substrate; and
backgrinding the Si substrate to a thickness of about 1 to about 100 μm.

16. The method of claim 14, wherein the Ge or Ge₁₋ₓSnₓ layer is formed by gas source molecular beam epitaxy, chemical vapor deposition, plasma enhanced chemical vapor deposition, laser assisted chemical vapor deposition, and atomic layer deposition.

17. The method of claim 14, wherein a Ge layer is formed directly on the Si substrate having a threading dislocation density below 10⁵/cm², wherein the Ge layer is formed by contacting the Si substrate with a chemical vapor comprising an admixture of (a) (H₃Ge)₂CH₂, H₃GeCH₃, or a mixture thereof; and (b) Ge₂H₆, wherein Ge₂H₆ is in excess.

18. The method of claim 14, wherein a Ge₁₋ₓSnₓ layer is formed directly on the Si substrate and the Ge₁₋ₓSnₓ layer is formed by contacting the Si substrate with a chemical vapor comprising Ge₂H₆ and SnD₄.

19. The method of claim 18, wherein the chemical vapor comprises H₂.

20. A solar cell comprising a semiconductor structure according to claim 1.
